(19) United States
(12) Patent Application Publication
(10) Pub. No.: US 2014/0377899 A1
(43) Pub. Date: Dec. 25, 2014

(54) LIGHT EMITTING DIODE CHIP MANUFACTURING METHOD

(71) Applicant: Lextar Electronics Corporation, Hsinchu (TW)

(72) Inventors: Tzu Hung CHOU, Zhongli City (TW); Cheng Chun LAN, New Taipei City (TW); Chi Chung CHAO, Taichung City (TW)

(73) Assignee: Lextar Electronics Corporation, Hsinchu (TW)

(21) Appl. No.: 14/143,309

(22) Filed: Dec. 30, 2013

(30) Foreign Application Priority Data
Jun. 19, 2013 (TW) 102121772

(51) Int. Cl. H01L 33/14

(52) U.S. Cl. CPC H01L 33/145
USPC 438/43

(57) ABSTRACT

A light emitting diode chip manufacturing method includes the following steps: a substrate is provided. A first semiconductor layer is formed on the substrate. A light-emitting layer is formed on a portion of the first semiconductor layer, and the surface of the first semiconductor layer not covered by the light-emitting layer is exposed. A second semiconductor layer is formed on the light-emitting layer. A hard shielding layer is formed on the second semiconductor layer and the exposed surface of the first semiconductor layer, such that a multi-layer stacked structure is formed on the substrate. A cutting treatment is performed. An etching treatment is performed. The hard shielding layer is patterned to form a current blocking layer on the second semiconductor layer, and the current blocking layer is made of the hard shielding layer.

### RELATED APPLICATIONS

This application claims priority to Taiwan Application Serial Number 102121772, filed Jun. 19, 2013, which is herein incorporated by reference.

### BACKGROUND

1. Field of Invention

The present invention relates to a light emitting diode chip manufacturing method.

2. Description of Related Art

Conventionally, in manufacturing a light emitting diode chip, an N-type semiconductor layer (e.g., N-GaN), a light emitting layer, a P-type semiconductor layer (e.g., P-GaN), and a hard mask (HM) layer are sequently stacked on a substrate. Thereafter, a laser cutting process and a sidewall etching (SWE) process are applied to the aforesaid stacked structure. The purpose of etching the sidewalls of the N-type semiconductor layer, the light emitting layer, and the P-type semiconductor layer is to improve the brightness of light output. The material of the hard mask is silicon dioxide, such that the hard mask can prevent the film surfaces of the N-type semiconductor layer, the light emitting layer, and the P-type semiconductor layer from the damages during the cutting process and the etching process. However, if the compactness of the hard mask layer is insufficient, the anti-etching ability of the hard mask layer is reduced, so as to lower the protection for the film surfaces of the N-type semiconductor layer, the light emitting layer, and the P-type semiconductor layer.

After the cutting process and the etching process, the hard mask layer is removed, and silicon dioxide films are formed on the P-type semiconductor layer and the surface of the N-type semiconductor layer that is not covered by the P-type semiconductor layer in a chemical vapor deposition (CVD) method. Next, the silicon dioxide film on the N-type semiconductor layer is removed, and the silicon dioxide film on the P-type semiconductor layer is patterned. Finally, a positive electrode is located above the patterned silicon dioxide film, and a negative electrode is located on the N-type semiconductor layer. The silicon dioxide film (referred to as a current block; CB) can block a current. Therefore, when the current passes through the silicon dioxide film, the current would be transversely conducted to reduce the probability of a light shielded by the positive electrode and improve the light output.

However, in the aforesaid manufacturing method, it is required to remove the hard mask layer, as well as the silicon dioxide film on the N-type semiconductor layer so as to locate the negative electrode. As a result, the manufacturing cost and time of light emitting diode chips are increased.

### SUMMARY

An aspect of the present invention is to provide a light emitting diode chip manufacturing method.

According to an embodiment of the present invention, a light emitting diode chip manufacturing method includes the following steps: a substrate is provided. A first semiconductor layer is formed on the substrate. A light-emitting layer is formed on a portion of the first semiconductor layer, and the surface of the first semiconductor layer not covered by the light-emitting layer is exposed. A second semiconductor layer is formed on the light-emitting layer. A hard shielding layer is formed on the second semiconductor layer and the exposed surface of the first semiconductor layer, such that a multi-layer stacked structure is formed on the substrate. A cutting treatment is performed, such that the multi-layer stacked structure on the substrate is cut to form a plurality of dies. An etching treatment is performed, such that the sidewalls of the light-emitting layer and the first and second semiconductor layers are etched to form an under cut structure. The hard shielding layer is patterned to form a current blocking layer on the second semiconductor layer, and the current blocking layer is made of the hard shielding layer.

In an embodiment of the present invention, patterning the hard shielding layer includes: a patterned photoresist layer on the hard shielding layer is formed. The hard shielding layer not covered by the patterned photoresist layer is etched to form the current blocking layer on the second semiconductor layer. The patterned photoresist layer is removed.

In an embodiment of the present invention, the light emitting diode chip manufacturing method further includes: a transparent conductive layer is formed to cover the current blocking layer and the surface of the second semiconductor layer that is not shielded by the current blocking layer.

In an embodiment of the present invention, the light emitting diode chip manufacturing method further includes: a first electrode is formed on the exposed first semiconductor layer. A second electrode is formed on the transparent conductive layer, and the position of the second electrode overlaps the position of the current blocking layer.

In an embodiment of the present invention, the area of the second electrode is equal to the area of the current blocking layer, and the edge of the second electrode is aligned with the edge of the current blocking layer.

In an embodiment of the present invention, the hard shielding layer is made of a material that includes silicon dioxide.

In an embodiment of the present invention, the substrate is a sapphire substrate.

In an embodiment of the present invention, the first and second semiconductor layers are made of a material that includes gallium nitride.

In an embodiment of the present invention, performing the cutting treatment is achieved by laser cutting or diamond blade cutting.

In an embodiment of the present invention, performing the etching treatment is achieved by wet etching.

Another aspect of the present invention is to provide a light emitting diode chip manufacturing method.

According to an embodiment of the present invention, a light emitting diode chip manufacturing method includes the following steps: a substrate is provided. A first semiconductor layer is formed on the substrate. A light-emitting layer is formed on a portion of the first semiconductor layer, and the surface of the first semiconductor layer not covered by the light-emitting layer is exposed. A second semiconductor layer is formed on the light-emitting layer. A hard shielding layer is formed on the second semiconductor layer and the exposed surface of the first semiconductor layer, such that a multi-layer stacked structure is formed on the substrate. The hard shielding layer is patterned to form a current blocking layer on the second semiconductor layer, and the current blocking layer is made of the hard shielding layer.

In an embodiment of the present invention, patterning the hard shielding layer includes: a patterned photoresist layer on the hard shielding layer is formed. The hard shielding layer not covered by the patterned photoresist layer is etched to form the current blocking layer on the second semiconductor layer. The patterned photoresist layer is removed.

In an embodiment of the present invention, the light emitting diode chip manufacturing method further includes: a transparent conductive layer is formed to cover the current blocking layer and the surface of the second semiconductor layer that is not shielded by the current blocking layer.

In an embodiment of the present invention, the light emitting diode chip manufacturing method further includes: a first electrode is formed on the exposed first semiconductor layer. A second electrode is formed on the transparent conductive layer, and the position of the second electrode overlaps the position of the current blocking layer.

In an embodiment of the present invention, the area of the second electrode is equal to the area of the current blocking layer, and the edge of the second electrode is aligned with the edge of the current blocking layer.

In an embodiment of the present invention, the hard shielding layer is made of a material that includes silicon dioxide.

In an embodiment of the present invention, the substrate is a sapphire substrate.

In the aforementioned embodiments of the present invention, since the light emitting diode chip manufacturing method of the present invention can directly utilize the current blocking layer made of the patterned hard shielding layer to replace a conventional silicon dioxide film formed on the second semiconductor layer, conventional processes of entirely removing the hard shielding layer, forming silicon dioxide films on the first and second semiconductor layers, and removing the silicon dioxide film on the first semiconductor layer can be skipped. The current blocking layer made of the hard shielding layer can be used to block currents. Therefore, when a current passes through the current blocking layer that is under an electrode (e.g., a positive electrode), the current would transversely conduct to reduce the probability of a light shielded by the electrode and improve the light output. Moreover, when the hard shielding layer is patterned, the hard shielding layer on the first semiconductor layer can be removed at the same time, such that another electrode (e.g., a negative electrode) can be located on the first semiconductor layer. As a result, compared with conventional arts, the light emitting diode chip manufacturing method of the present invention can reduce the manufacturing cost and the manufacturing time of light emitting diode chips.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a flow chart of a light emitting diode chip manufacturing method according to an embodiment of the present invention;

FIG. 2 is a cross-sectional view after a first semiconductor layer is formed on a substrate according to an embodiment of the present invention;

FIG. 3 is a cross-sectional view after a light emitting layer is formed on the first semiconductor layer shown in FIG. 2;

FIG. 4 is a cross-sectional view after a second semiconductor layer is formed on the light emitting layer shown in FIG. 3;

FIG. 5 is a cross-sectional view after a hard shielding layer is formed on the first and second semiconductor layers shown in FIG. 4;

FIG. 6 is a cross-sectional view of the substrate and a multi-layer stacked structure shown in FIG. 5 after a cutting treatment is performed;

FIG. 7 is a cross-sectional view of the sidewalls of the light emitting layer and the first and second semiconductor layers shown in FIG. 6 after an etching treatment is performed;

FIG. 8 is a cross-sectional view after a patterned photoresist layer is formed on the hard shielding layer shown in FIG. 7;

FIG. 9 is a cross-sectional view of the hard shielding layer shown in FIG. 8 after being etched;

FIG. 10 is a cross-sectional view of the photoresist layer shown in FIG. 9 after being removed;

FIG. 11 is a cross-sectional view of a current blocking layer shown in FIG. 10 after being covered by a transparent conductive layer;

FIG. 12 is a cross-sectional view after a first electrode is formed on the first semiconductor layer shown in FIG. 11 and a second electrode is formed on the second semiconductor layer shown in FIG. 11; and

FIG. 13 is a flow chart of a light emitting diode chip manufacturing method according to an embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

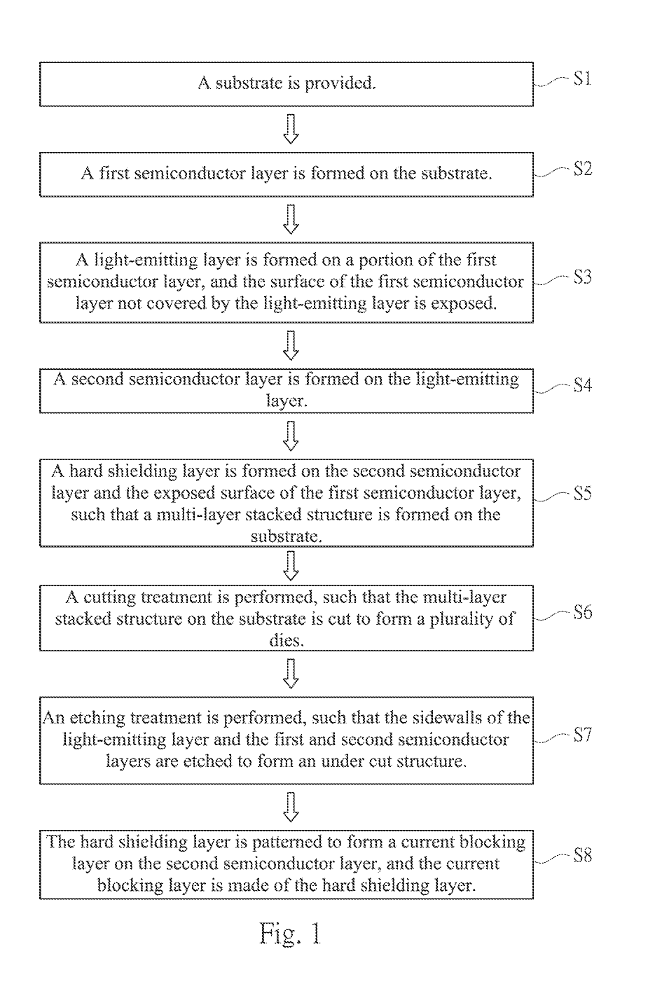

FIG. 1 is a flow chart of a light emitting diode chip manufacturing method according to an embodiment of the present invention. The light emitting diode chip manufacturing method includes the following steps. In step S1, a substrate is provided. Thereafter in step S2, a first semiconductor layer is formed on the substrate. Next in step S3, a light-emitting layer is formed on a portion of the first semiconductor layer, and the surface of the first semiconductor layer not covered by the light-emitting layer is exposed. Thereafter in step S4, a second semiconductor layer is formed on the light-emitting layer. Next in step S5, a hard shielding layer is formed on the second semiconductor layer and the exposed surface of the first semiconductor layer, such that a multi-layer stacked structure is formed on the substrate. Thereafter in step S6, a cutting treatment is performed, such that the multi-layer stacked structure on the substrate is cut to form a plurality of dies. Next in step S7, an etching treatment is performed, such that the sidewalls of the light-emitting layer and the first and second semiconductor layers are etched to form an under cut structure. Finally in step S8, the hard shielding layer is patterned to form a current blocking layer on the second semiconductor layer, and the current blocking layer is made of the hard shielding layer.

In the following descriptions, the aforesaid steps S1 to S8 of the light emitting diode chip manufacturing method will be described in detail.

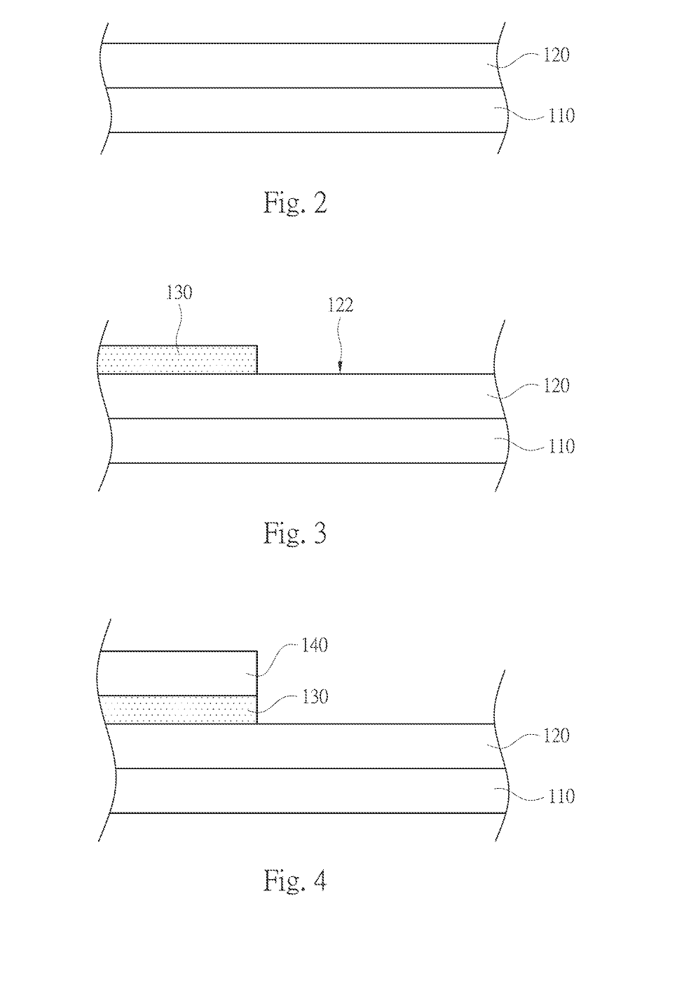

FIG. 2 is a cross-sectional view after a first semiconductor layer 120 is formed on a substrate 110 according to an embodiment of the present invention. FIG. 3 is a cross-sectional view after a light emitting layer 130 is formed on the first semiconductor layer 120 shown in FIG. 2. As shown in FIG. 2 and FIG. 3, after the first semiconductor layer 120 is formed on the substrate 110, the light emitting layer 130 can be formed on a portion of the first semiconductor layer 120. As a result, the surface 122 of the first semiconductor layer 120 not covered by the light-emitting layer 130 is exposed. In this embodiment, the substrate 100 may be, but not limited to, a sapphire substrate. The first semiconductor layer may be made of a material that includes gallium nitride, such as N-type gallium nitride (N-GaN).

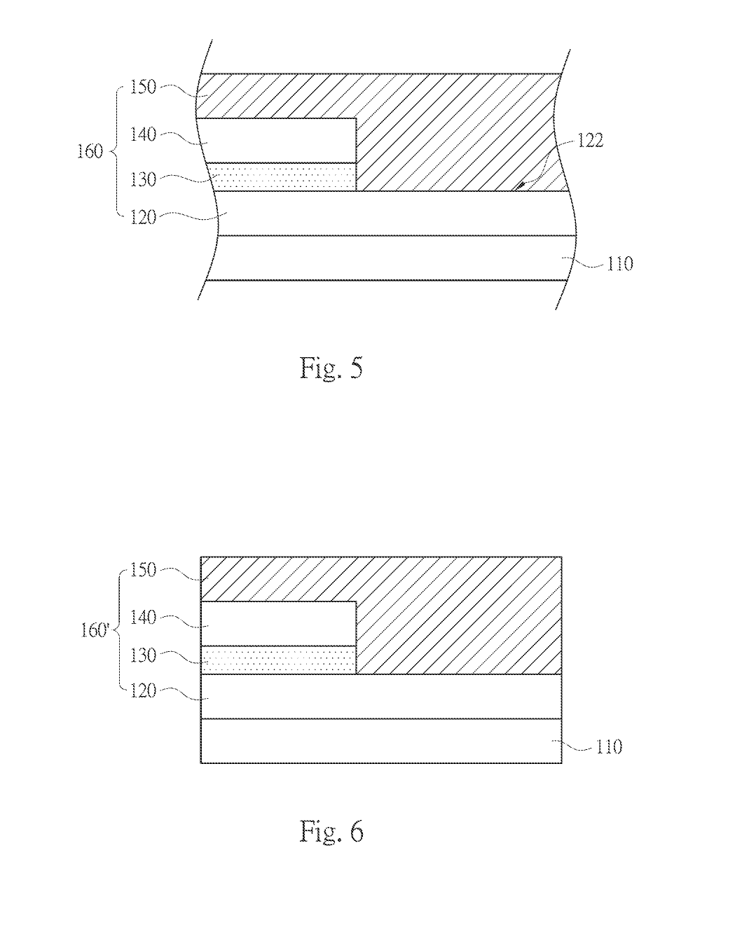

FIG. 4 is a cross-sectional view after a second semiconductor layer 140 is formed on the light emitting layer 130 shown in FIG. 3. FIG. 5 is a cross-sectional view after a hard shielding layer 150 is formed on the first and second semiconductor layers 120, 140 shown in FIG. 4. As shown in FIG. 4 and FIG. 5, after the light emitting layer 130 is formed on the first semiconductor layer 120, the second semiconductor layer 140 can be formed on the light emitting layer 130. Thereafter, the hard shielding layer 150 is formed on the second semiconductor layer 140 and the exposed surface 122 of the first semiconductor layer 120, such that a multi-layer stacked structure 160 is formed on the substrate 110. In this embodiment, the second semiconductor layer may be made of a material that includes gallium nitride, such as P-type gallium nitride (P-GaN). The hard shielding layer 150 may be made of a material that includes silicon dioxide (SiO₂), and silicon dioxide may be formed by SiH₄ and N₂O. When the hard shielding layer 150 is manufactured, the flow rate ratio of SiH₄ and N₂O may be in a range from 0.5 to 10, the temperature may be controlled greater than 250° C., and the radio frequency (RF) power may be controlled greater than 250 W. The compactness of the hard shielding layer 150 manufactured with the aforesaid conditions is improved, and the anti-etching ability of the hard shielding layer 150 is also improved, such that the hard shielding layer 150 can be used to be as the material of a current blocking (CB) layer.

FIG. 6 is a cross-sectional view of the substrate 110 and the multi-layer stacked structure 160 shown in FIG. 5 after a cutting treatment is performed. As shown in FIG. 5 and FIG. 6, after the hard shielding layer 150 is formed on the second semiconductor layer 140 and the exposed surface 122 of the first semiconductor layer 120, the cutting treatment can be performed to the multi-layer stacked structure 160 located on the substrate 110, such that the multi-layer stacked structure 160 is cut to form a plurality of dies 160′. In FIG. 6, only shows a single die 160′. In practice, after the structure shown in FIG. 5 is cut, other structures such as FIG. 6 would be formed. In this embodiment, performing the cutting treatment may be achieved by laser cutting or diamond blade cutting, but the present invention is not limited in this regard.

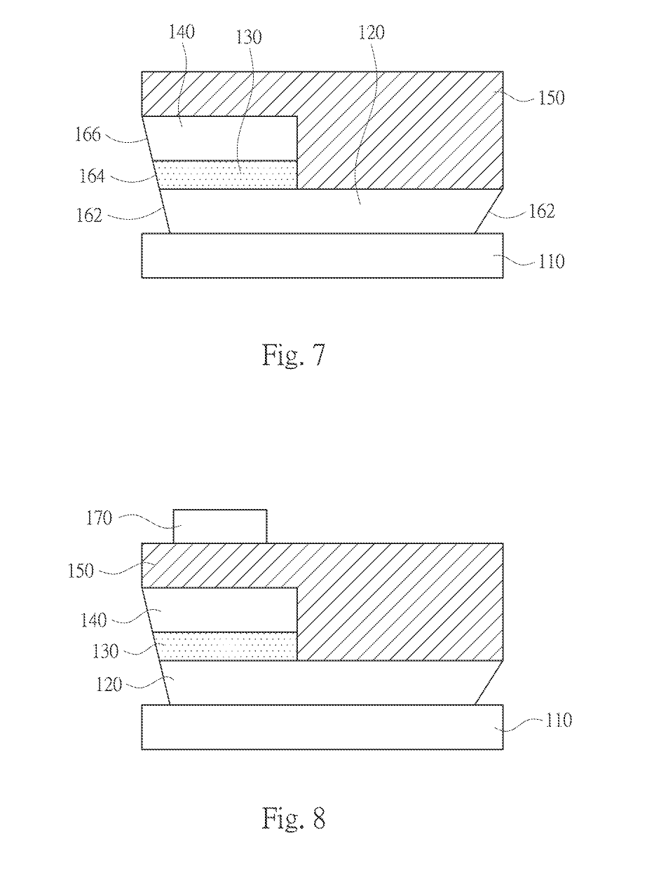

FIG. 7 is a cross-sectional view of the sidewalls of the light emitting layer 130 and the first and second semiconductor layers 120, 140 shown in FIG. 6 after an etching treatment is performed. As shown in FIG. 6 and FIG. 7, after the cutting treatment is performed to the multi-layer stacked structure 160 on the substrate 110, the etching treatment can be performed to the structure shown in FIG. 6, such that the sidewall 162 of the first semiconductor layer 120, the sidewall 164 of the light emitting layer 130, and the sidewall 166 of the second semiconductor layer 140 are etched to form an under cut structure. In this embodiment, performing the etching treatment may be achieved by wet etching. Since the compactness and the anti-etching ability of the hard shielding layer 150 are improved, the hard shielding layer 150 can prevent the film surfaces (i.e., horizontal surfaces) of the light emitting layer 130 and the first and second semiconductor layers 120, 140 from damages during the aforesaid cutting treatment and the aforesaid etching treatment.

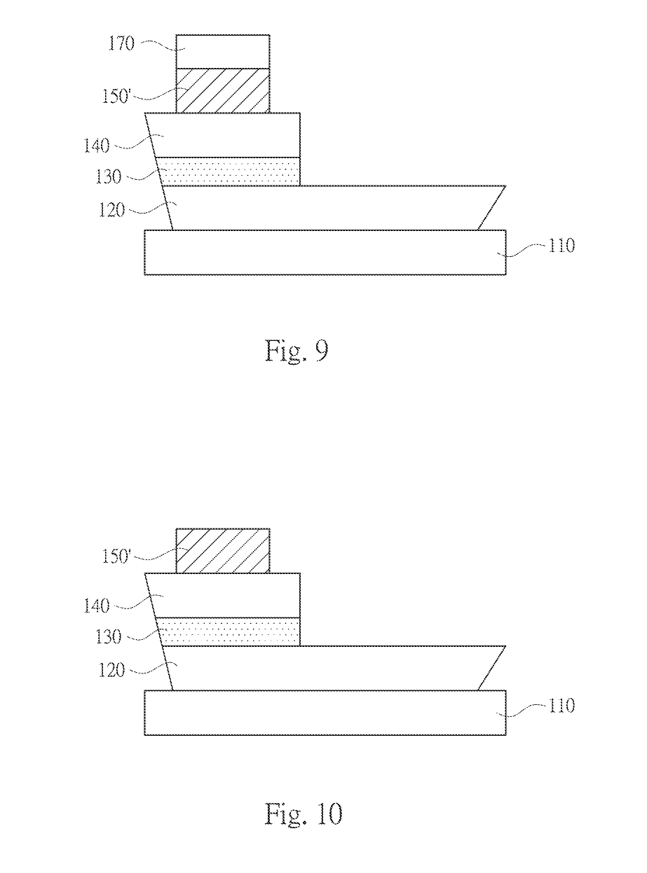

FIG. 8 is a cross-sectional view after a patterned photoresist layer 170 is formed on the hard shielding layer 150 shown in FIG. 7. FIG. 9 is a cross-sectional view of the hard shielding layer 150 shown in FIG. 8 after being etched. As shown in FIG. 8 and FIG. 9, after the sidewalls 162, 164, 166 shown in FIG. 7 are etched, the patterned photoresist layer 170 can be formed on the hard shielding layer 150. Thereafter, the hard shielding layer 150 not covered by the patterned photoresist layer 170 can be removed by an etching process, such that the hard shielding layer 150 protected by the photoresist layer 170 can form a current blocking layer 150′ on the second semiconductor layer 140.

FIG. 10 is a cross-sectional view of the photoresist layer 170 shown in FIG. 9 after being removed. As shown in FIG. 9 and FIG. 10, after the current blocking layer 150′ is formed on the second semiconductor layer 140, the patterned photoresist layer 170 can be removed. That is to say, after the hard shielding layer 150 is patterned, the current blocking layer 150′ made of the hard shielding layer 150 can be formed on the second semiconductor layer 140.

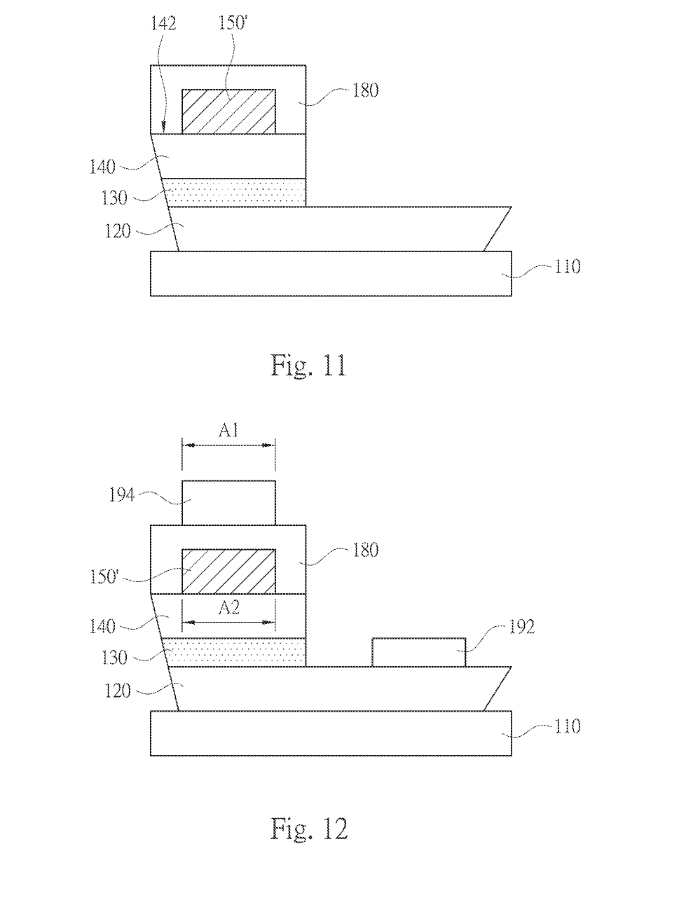

FIG. 11 is a cross-sectional view of the current blocking layer 150′ shown in FIG. 10 after being covered by a transparent conductive layer 180. FIG. 12 is a cross-sectional view after a first electrode 192 is formed on the first semiconductor layer 120 shown in FIG. 11 and a second electrode 194 is formed on the second semiconductor layer 194 shown in FIG. 11. As shown in FIG. 11 and FIG. 12, after the current blocking layer 150′ is formed on the second semiconductor layer 140, the transparent conductive layer 180 can be formed to cover the current blocking layer 150′ and the surface 142 of the second semiconductor layer 140 that is not shielded by the current blocking layer 150′. Thereafter, a first electrode 192 can be formed on the exposed first semiconductor layer 120. A second electrode 194 can be formed on the transparent conductive layer 180, and the position of the second electrode 194 overlaps the position of the current blocking layer 150′. In this embodiment, the area Al of the second electrode 194 is equal to the area A2 of the current blocking layer 150′, and the edge of the second electrode 194 is aligned with the edge of the current blocking layer 150′, but the present invention is not limited in this regard.

The structure shown in FIG. 12 is a light emitting diode chip manufactured by the aforesaid light emitting diode chip manufacturing method. Since the light emitting diode chip manufacturing method can directly utilize the current blocking layer 150′ made of the patterned hard shielding layer 150 to replace a conventional silicon dioxide film formed on the second semiconductor layer 140, conventional processes of entirely removing the hard shielding layer 150, forming silicon dioxide films on the first and second semiconductor layers 120, 140, and removing the silicon dioxide film on the first semiconductor layer 120 can be skipped. The current blocking layer 150′ made of the hard shielding layer 150 can be used to block currents. Therefore, when a current passes through the current blocking layer 150′ that is under the second electrode 194 (e.g., a positive electrode), the current would transversely conduct to reduce the probability of a light shielded by the second electrode 194 and improve the light output. Moreover, when the hard shielding layer 150 is patterned, the hard shielding layer 150 on the first semiconductor layer 120 can be removed by an etching process at the same time, such that the first electrode 192 (e.g., a negative electrode) can be located on the first semiconductor layer 120. As a result, compared with conventional arts, the light emitting diode chip manufacturing method of the present invention can significantly reduce the manufacturing cost and the manufacturing time of light emitting diode chips.

It is to be noted that the connection relationships and materials of the elements described above will not be repeated in the following descriptions, and only aspects related to other light emitting diode chip manufacturing methods will be described.

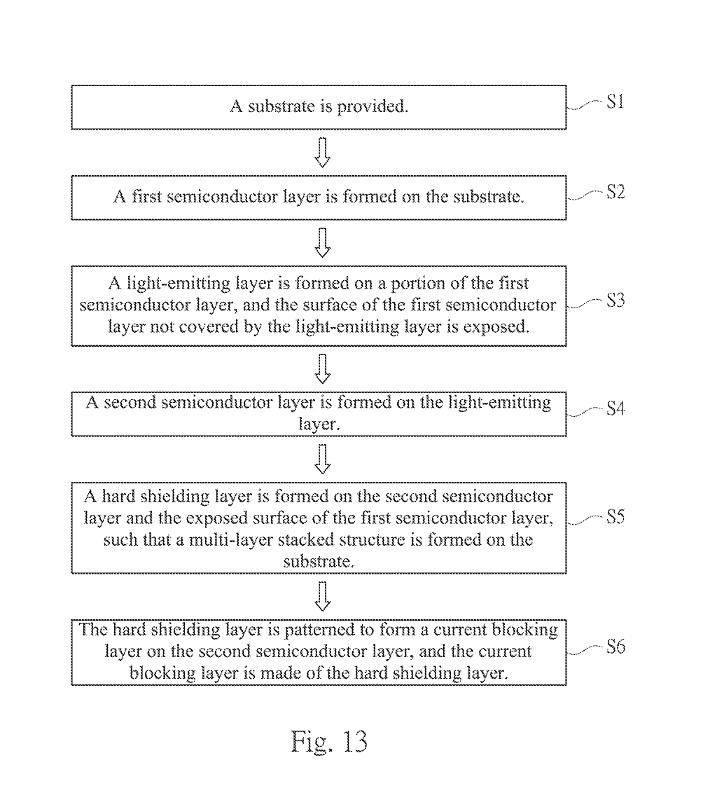

FIG. 13 is a flow chart of a light emitting diode chip manufacturing method according to an embodiment of the present invention. The light emitting diode chip manufacturing method includes the following steps. In step S1, a substrate is provided. Thereafter in step S2, a first semiconductor layer is formed on the substrate. Next in step S3, a light-emitting layer is formed on a portion of the first semiconductor layer, and the surface of the first semiconductor layer not covered by the light-emitting layer is exposed. Thereafter in step S4, a second semiconductor layer is formed on the light-emitting layer. Next in step S5, a hard shielding layer is formed on the second semiconductor layer and the exposed surface of the first semiconductor layer, such that a multi-layer stacked structure is formed on the substrate. Finally in step S6, the hard shielding layer is patterned to form a current blocking layer on the second semiconductor layer, and the current blocking layer is made of the hard shielding layer.

The difference between this embodiment and the embodiment shown in FIG. 1 is that the light emitting diode chip manufacturing method omits the steps related to the cutting treatment and the etching treatment of FIG. 1. Since the steps S1 to S6 are the same as the embodiment shown in FIG. 1 except the cutting treatment and the etching treatment, not be repeated in description.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light emitting diode chip manufacturing method comprising:
providing a substrate;
forming a first semiconductor layer on the substrate;
forming a light-emitting layer on a portion of the first semiconductor layer and exposing a surface of the first semiconductor layer that is not covered by the light-emitting layer;
forming a second semiconductor layer on the light-emitting layer;
forming a hard shielding layer on the second semiconductor layer and the exposed surface of the first semiconductor layer, such that a multi-layer stacked structure is formed on the substrate;
performing a cutting treatment, such that the multi-layer stacked structure on the substrate is cut to form a plurality of dies;
performing an etching treatment, such that the sidewalls of the light-emitting layer and the first and second semiconductor layers are etched to form an under cut structure; and
patterning the hard shielding layer to form a current blocking layer on the second semiconductor layer, wherein the current blocking layer is made of the hard shielding layer.

2. The light emitting diode chip manufacturing method of claim 1, wherein patterning the hard shielding layer comprises:
forming a patterned photoresist layer on the hard shielding layer;
etching the hard shielding layer not covered by the patterned photoresist layer to form the current blocking layer on the second semiconductor layer; and
removing the patterned photoresist layer.

3. The light emitting diode chip manufacturing method of claim 2, further comprising:
forming a transparent conductive layer to cover the current blocking layer and a surface of the second semiconductor layer that is not shielded by the current blocking layer.

4. The light emitting diode chip manufacturing method of claim 3, further comprising:
forming a first electrode on the exposed first semiconductor layer; and
forming a second electrode on the transparent conductive layer, wherein a position of the second electrode overlaps a position of the current blocking layer.

5. The light emitting diode chip manufacturing method of claim 4, wherein an area of the second electrode is equal to an area of the current blocking layer, and an edge of the second electrode is aligned with an edge of the current blocking layer.

6. The light emitting diode chip manufacturing method of claim 1, wherein the hard shielding layer is made of a material that comprises silicon dioxide.

7. The light emitting diode chip manufacturing method of claim 1, wherein the substrate is a sapphire substrate.

8. The light emitting diode chip manufacturing method of claim 1, wherein the first and second semiconductor layers are made of a material that comprises gallium nitride.

9. The light emitting diode chip manufacturing method of claim 1, wherein performing the cutting treatment is achieved by laser cutting or diamond blade cutting.

10. The light emitting diode chip manufacturing method of claim 1, wherein performing the etching treatment is achieved by wet etching.

11. A light emitting diode chip manufacturing method comprising:
providing a substrate;
forming a first semiconductor layer on the substrate;
forming a light-emitting layer on a portion of the first semiconductor layer and exposing a surface of the first semiconductor layer that is not covered by the light-emitting layer;
forming a second semiconductor layer on the light-emitting layer;
forming a hard shielding layer on the second semiconductor layer and the exposed surface of the first semiconductor layer, such that a multi-layer stacked structure is formed on the substrate; and
patterning the hard shielding layer to form a current blocking layer on the second semiconductor layer, wherein the current blocking layer is made of the hard shielding layer.

12. The light emitting diode chip manufacturing method of claim 11, wherein patterning the hard shielding layer comprises:
forming a patterned photoresist layer on the hard shielding layer;
etching the hard shielding layer not covered by the patterned photoresist layer to form the current blocking layer on the second semiconductor layer; and
removing the patterned photoresist layer.

13. The light emitting diode chip manufacturing method of claim 12, further comprising:
forming a transparent conductive layer to cover the current blocking layer and a surface of the second semiconductor layer that is not shielded by the current blocking layer.

14. The light emitting diode chip manufacturing method of claim 13, further comprising:
forming a first electrode on the exposed first semiconductor layer; and
forming a second electrode on the transparent conductive layer, wherein a position of the second electrode overlaps a position of the current blocking layer.

15. The light emitting diode chip manufacturing method of claim 14, wherein an area of the second electrode is equal to an area of the current blocking layer, and an edge of the second electrode is aligned with an edge of the current blocking layer.

16. The light emitting diode chip manufacturing method of claim 11, wherein the hard shielding layer is made of a material that comprises silicon dioxide.

17. The light emitting diode chip manufacturing method of claim 11, wherein the substrate is a sapphire substrate.
